(19) United States
(12) Patent Application Publication
(10) Pub. No.: US 2010/0265975 A1
(43) Pub. Date: Oct. 21, 2010

(54) EXTENDED CAVITY SEMICONDUCTOR LASER DEVICE WITH INCREASED INTENSITY

(75) Inventors: Johannes Baier, Wuerselen (DE); Ulrich Weichmann, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/741,061

(22) PCT Filed: Nov. 3, 2008
(86) PCT No.: PCT/IB08/54552

§ 371 Date: May 3, 2010

(30) Foreign Application Priority Data
Nov. 7, 2007 (EP) 07120175.0

(51) Int. Cl. H01S 3/13; H01S 5/42

(52) U.S. Cl. 372/29.014; 372/50.124

(57) ABSTRACT

The present invention relates to an extended cavity semiconductor laser device comprising an array of at least two semiconductor gain elements (20, 21), each of said semiconductor gain elements (20, 21) comprising a layer structure (1) forming a first end mirror (2) and an active medium (3). A coupling component (22) inside of the device combines fundamental laser radiation emitted by said array of semiconductor gain elements (20, 21) to a single combined laser beam (25). A second end mirror (23) reflects at least part of said single combined laser beam (23) back to said coupling component (22) to form extended cavities with the first end mirrors (2). Due to this coherent coupling of several extended cavity semiconductor lasers a single beam of the fundamental radiation is generated with increased intensity, good beam profile and narrow spectral band width. This beam of increased intensity is much better suited for frequency conversion via upconversion or via second harmonic generation than the individual beams of the array of extended cavity semiconductor laser components. The efficiency of frequency conversion is therefore greatly enhanced.

### FIELD OF THE INVENTION

The present invention relates to an extended cavity semiconductor laser device comprising an array of at least two semiconductor gain elements, each of said semiconductor gain elements comprising a layer structure forming a first end mirror and an active medium.

### BACKGROUND OF THE INVENTION

The lack of integrated laser sources in the green wavelength region has until now hindered the widespread use of lasers for display or illumination applications. Nowadays used laser sources for the green wavelength region rely on frequency conversion either by upconversion or by second harmonic generation (SHG) of an infrared laser source. For the efficiency of the frequency conversion process the intensity of the pump source is of utmost importance. While the conversion efficiency of upconversion processes in most cases depends linearly on the pump intensity, second harmonic generation depends even quadratically on the pump intensity. Therefore pump sources that deliver a high intensity beam are highly desired for efficient frequency conversion.

Quite compact setups that rely on upconversion or second harmonic generation can be realized with optically and especially with electrically pumped surface emitting semiconductor lasers. An example for such an electrically pumped, intracavity frequency doubled laser is based on a vertical cavity surface emitting laser (VCSEL) with an extended cavity (VECSEL: vertical extended cavity surface emitting laser) as shown in FIG. 1. Inside the extended cavity a frequency doubling crystal converts the infrared radiation from this VECSEL into visible radiation. Known frequency doubling crystals are made from a non-linear material such as for example periodically poled Lithium Niobate (PPLN), periodically poled KTP (PPKTP) or other materials generally used for second harmonic generation like BBO, BiBO, KTP or LBO. For efficient frequency doubling, high infrared power densities as well as narrow-band infrared operation are needed. The latter is for example realized by using a volume Bragg grating (VBG) as output coupler, which reflects the infrared radiation and transmits the frequency doubled radiation. This VBG has typically a narrow reflectivity bandwidth in the order of ˜0.2 nm. A partially transmissive DBR (distributed Bragg reflector), which is usually arranged at the intracavity side of the active medium of a VECSEL, is needed to lower the laser threshold for this low-gain device. Furthermore for an efficient generation of second harmonic radiation the infrared laser has to be polarized, as the second harmonic generation process usually works only for one specific polarization and infrared light having the other polarization direction would be lost for second harmonic generation. This is achieved with some kind of polarization control in the cavity, which can for example be a polarizing beam splitter or a mirror placed under an appropriate angle. A further complication of this setup is the thermal management. While the infrared laser has a relatively broad operation range of about 10° C., in which the output power remains nearly constant, the temperature of the nonlinear material has to be controlled within a temperature range of smaller than 1° C.

While upconversion in glass-hosts exhibits a relatively broad absorption profile and has accordingly only low requirements on the spectral width of the pump diode, upconversion in crystals and especially second harmonic generation are most efficient for narrow-band pump sources. Therefore, some quite complicated approaches for second harmonic generation lasers have been suggested where the bandwidth of the pump diode is narrowed by additional optical elements like filters or volume Bragg gratings in the pump laser resonator.

Due to thermal constrains the output power of a single device is in many cases limited to some hundred milliwatts. For applications, which require higher output powers, several single devices are coupled to an array of lasers. In this case the wall-plug efficiency of the total device is the same as the wall plug efficiency of the single laser source.

Another approach is described in U.S. Pat. No. 5,131,002 A. This document discloses an extended cavity semiconductor laser system wherein multiple segments of semiconductor material separated from one another are excited with an array of pump sources. This pumping system spreads out the thermal load while providing a high power laser beam. The series operation of the multiple segments of the active medium inside of the extended laser cavity also results in an improved beam quality of the outcoupled laser beam.

### SUMMARY OF THE INVENTION

It is an object of the present invention to provide a semiconductor laser device, in particular a VECSEL device, generating high power fundamental laser radiation with significantly reduced spectral bandwidth.

The object is achieved with the extended cavity semiconductor laser device, in particular a VECSEL device, according to claim 1. Advantageous embodiments of the device are subject matter of the dependent claims or are described in the subsequent portions of the description.

The extended cavity semiconductor laser device comprises an array of at least two semiconductor gain elements, each of these semiconductor gain elements comprising a layer structure forming a first end mirror and an active medium. A coupling component combining fundamental laser radiation emitted by said array of semiconductor gain elements to a single combined laser beam is arranged between the array of semiconductor gain elements and a second end mirror which reflects at least part of the single combined laser beam back to said coupling components to form extended cavities with said first end mirrors. In a most preferred embodiment the extended cavity semiconductor laser device is a VECSEL device based on an array of VCSEL components representing the semiconductor gain elements. Therefore the proposed laser device and advantageous embodiments of this device are described in the following using the example of a VECSEL. Nevertheless the invention and preferred embodiments also apply to other extended cavity laser devices like e.g. edge emitting lasers.

The VECSEL components of the array preferably have the same construction as common VCSELs with the difference that one of the DBR's forming the end mirrors of these VCSELs is partially transmissive to such an extend that lasing is not achieved without an additional external end mirror. The array of such VECSEL components, which may be a one dimensional array or a two dimensional array, can be formed of a single substrate common to all of the VECSEL components. Furthermore, the array or each single VECSEL component may be arranged on an appropriate heat sink for heat dissipation during operation.

The invention is based on the coherent coupling of laser beams of several VECSELs via constructive interference. The beams of the different VECSEL components are overlaid via the coupling component which acts like an interferometric beam combiner. The beam combiner preferably provides one or several beam splitting regions for appropriately combining the different laser beams to one single laser beam. At such a beam splitting region, for example when combining two laser beams, a portion of one of the laser beams is reflected or transmitted outside of the extended cavity. Since the laser will always tend to operate in a mode which minimizes losses, the interference between both laser beams will adjust in such a way, that the beams in the loss channel will interfere destructively, while the beams in the extended cavity will interfere constructively. Therefore, even though in principle substantial losses would be expected in such a type of cavity, the losses are avoided by destructive interference and the two laser beams are constructively added resulting in a coherent emission of both beams. The same applies to the coupling of more than two laser beams when using an array of more than two VECSEL components. Due to this coherent coupling a significant spectral narrowing is achieved, since all coupled lasers have to share a common longitudinal cavity mode while operating in laser resonators of different length. The same argument also holds true for the transverse modes. Therefore the coherent coupling of the different VECSEL components also results in a substantial improvement of the beam quality. The output of the proposed VECSEL device is correspondingly increased with the number of VECSEL components included in the device. Due to the significant spectral narrowing, the improved beam quality and the higher intensity of the fundamental radiation, preferably infrared radiation, the proposed laser device can be very advantageously used for intracavity or extra cavity frequency conversion, in particular when using frequency converting crystals as for example crystals for second harmonic generation.

Due to the spectral narrowing of the coherently coupled laser beams, there is no need for any additional spectral selectivity inside of the cavity. Therefore, much simpler outcoupling mirrors than volume Bragg gratings can be employed. For example, cheap broadband dielectric mirrors can be used for outcoupling, or a dielectric coating can be directly applied to the exit surface of the optical coupling component, in which the laser beams are coupled. The proposed laser device allows a very compact construction for generating the desired laser radiation.

In order to generate frequency doubled radiation, for example in the green wavelength region, a frequency converting medium generating the upconverted laser radiation can be arranged outside of the external cavities of the coupled laser components in the beam path of the outcoupled fundamental laser beam. In this case, the second end mirror of the device is designed to form an outcoupling mirror for said fundamental laser radiation, i.e. it is partially transmissive for said fundamental laser radiation on the one hand but still allows the laser device to operate above the laser threshold. It goes without saying, that the outcoupled fundamental laser beam may be focused by appropriate optical elements like one or several lenses into the frequency converting medium.

Another possibility to generate the frequency doubled radiation is to arrange a frequency converting medium between the coupling component and the second end mirror of the device. In this case, the second end mirror is designed to form an outcoupling mirror for the converted laser radiation and to be highly reflective for the fundamental laser radiation.

In both cases the frequency converting medium may be a doped host material for frequency upconversion or a second harmonic generation crystal, as already described in the introductory portion of this description.

The coupling component preferably comprises two opposing reflective surfaces for beam coupling. One of these surfaces is highly reflective (reflectivity≧95%) for the fundamental laser radiation, whereas the other surface has a reflectivity of between 40 and 60%, preferably 50%, and a transmittance of between 40 and 60%, preferably 50%, for the fundamental laser radiation. With such a coupling component a large number of laser beams can be combined using multiple internal reflections between the two opposing surfaces. In one advantageous embodiment, in which frequency upconversion is performed outside of the extended cavities, the coupling component is directly attached to the second end mirror, i.e. the outcoupling mirror for the fundamental radiation, or this mirror is formed by an appropriate coating on an outcoupling surface of the coupling component. This results in a very compact construction of the whole device.

In a further advantageous embodiment, the second end mirror is attached to a translation stage with which the second end mirror may be displaced to vary the length of the extended cavities. Such a translation stage may be formed of an appropriate actuator, for example a piezo-actuator. When using an optical detector measuring the intensity of outcoupled laser radiation, the length of the laser cavities can be varied through an appropriate control unit based on the measured intensity. With such an arrangement, the operation of the laser device can be optimized to have desired properties, for example a maximum output intensity and/or a stable operation. This allows for compensating any cavity length detuning, which can appear for example when the temperature of the laser device varies during operation and the optical path lengths of the external cavities change due to the resulting refractive index changes within the semiconductor material.

When using the proposed laser device with a frequency converting medium, green laser radiation can be generated with high power. Therefore, such a device can advantageously be used as one of the components of a RGB laser source or as one of the light sources in a laser projection device.

These and other aspects of the invention will be apparent from and elucidated with reference to the embodiments described herein after.

### BRIEF DESCRIPTION OF THE DRAWINGS

The proposed semiconductor laser device is described in the following by way of examples in connection with the accompanying Figures without limiting the scope of protection as defined by the claims. The Figures show:

FIG. 1 an example of a VECSEL device with internal frequency doubling as known in the art;

FIG. 2 schematically a first example of the proposed laser device,

FIG. 3 schematically a second example of the proposed laser device;

FIG. 4 schematically a third example of the proposed laser device; and

FIG. 5 schematically a fourth example of the proposed laser device.

### DETAILED DESCRIPTION OF EMBODIMENTS

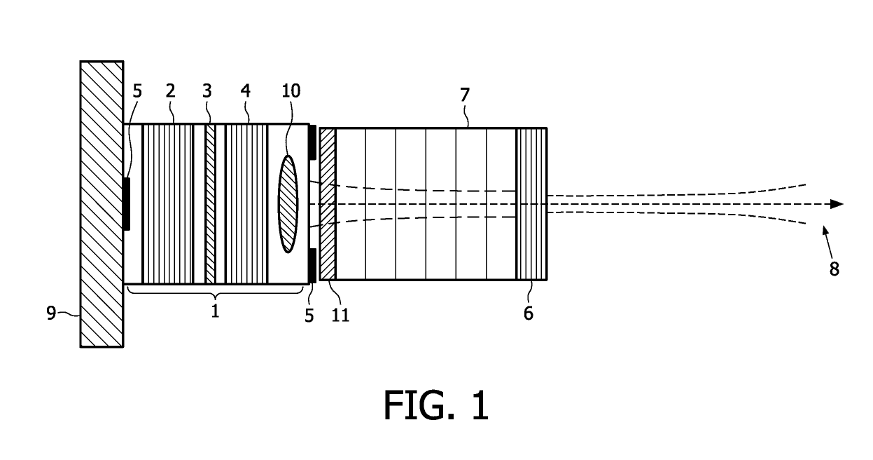

FIG. 1 shows a schematic view of an extended cavity vertical surface emitting laser (VECSEL) with intracavity frequency doubling as known in the art. The laser is formed of a layer structure 1 comprising a first end mirror 2, an active layer 3 and a partially transmissive DBR 4. The active layer 3, for example a quantum well structure based on GaAs is sandwiched between the DBR forming the first end mirror 2 and the partially transmissive DBR 4. The partially transmissive DBR 4 is needed to lower the laser threshold for this low gain device in order to avoid lasing between the first end mirror 2 and the partially transmissive DBR 4. Electrical contacts 5 are placed at both sides of this layer structure in order to inject the necessary charge carriers for lasing. The extended laser cavity is formed between an extended mirror 6 and the first end mirror 2. The extended mirror 6 is attached to a SHG crystal 7 arranged inside of the extended cavity. This second end mirror is designed to be highly reflective for the fundamental infrared radiation emitted by the active layer 3 and on the other hand forms an outcoupling mirror for the frequency doubled visible radiation. Therefore, this laser device emits a laser beam 8 in the visible wavelength region. The laser device is attached to a heat sink 9 for the required heat dissipation. Furthermore, a thermal lens 10 is indicated in the layer structure. This thermal lens 10 is generated during operation of the laser device due to a thermally induced refractive index modulation and results in a beam waist of the intracavity fundamental beam inside of the second harmonic generation crystal 7. This is also indicated in FIG. 1. A polarization control 11 is used inside of the extended cavity in order to generate the desired polarization for the frequency doubling crystal 7. This polarization control can be a polarizing beam splitter for example.

The laser power of such a VECSEL device is limited due to the heat generation in this device. Furthermore several measures have to be taken to spectrally narrow the fundamental laser radiation to enable efficient second harmonic generation.

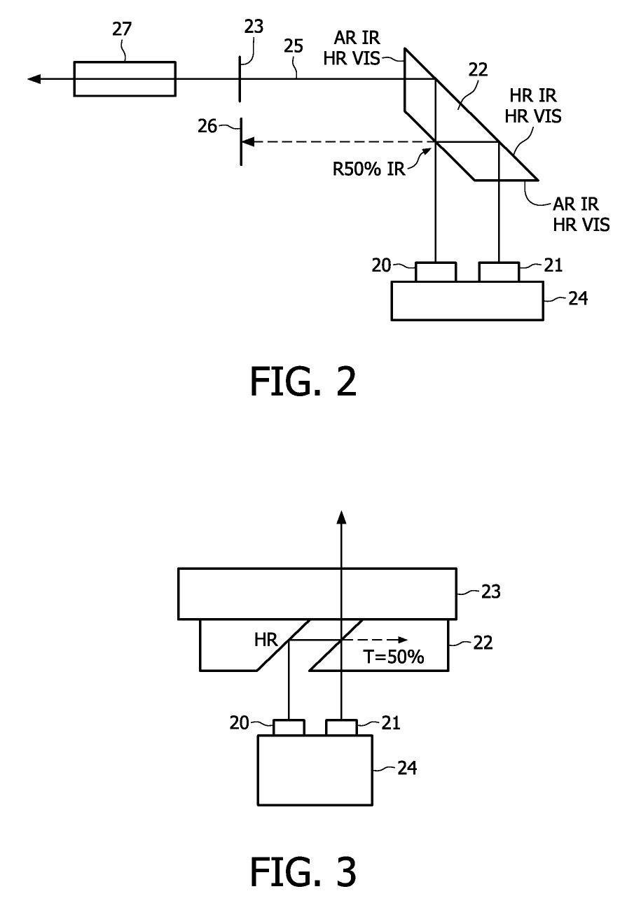

FIG. 2 shows an example of the laser device according to the present invention which achieves a significantly higher intensity of the fundamental laser radiation and at the same time ensures a narrow spectral band width of the fundamental radiation without the need of complicated additional measures. Such a laser device is therefore advantageously useful for upconversion like second harmonic generation. The proposed device uses two semiconductor gain elements 20, 21 which are arranged side by side on a common heat sink 24, for example a copper plate. The two semiconductor gain elements 20, 21 comprise a layer structure forming a first end mirror and an active medium. These semiconductor gain elements, for example, may be designed like the layer structure 1 of the VECSEL of FIG. 1.

The laser radiation emitted by these semiconductor gain elements 20, 21 is combined by a coupling component 22 to form a single laser beam 25. The coupling component 22 is an optical element which is coated with a high reflection coating on one side and with a coating with approximately 50% reflection on the opposite side (each for the fundamental infrared radiation). The optical element is made of a material transparent for the fundamental radiation, for example made of glass or of an appropriate plastic material. The radiation from the semiconductor gain elements 20, 21, also referred to as pump diodes, enters the optical element as depicted in FIG. 2. The radiation of the first semiconductor gain element 20 is partially reflected on the side surface of this component outside of the cavity. A beam stop 26 is arranged in this beam path in order to avoid any damage from the outcoupled portion. Nevertheless, at proper operation of the laser device, no radiation reaches the beam stop 26, since this path suffers from destructive interference of the laser radiation of the two semiconductor gain elements overlaid in this direction. The other portion of the laser radiation of semiconductor gain element 20 is overlaid over the radiation of the second semiconductor gain element 21 inside of the optical element to form the single beam 25. In order to avoid any losses on the other side surfaces of the optical element, these surfaces can be coated with a high reflection coating or with an antireflective coating for the fundamental infrared radiation as indicated in FIG. 2. A second end mirror 23 forms the two extended cavities with the first end mirrors of the semiconductor gain elements 20 and 21. This second end mirror 23 is designed as an outcoupling mirror for the fundamental infrared radiation. Therefore, part of the generated fundamental radiation is outcoupled at this mirror and directed to a second harmonic crystal 27 for second harmonic generation. In the present example, this second harmonic crystal 27 is a PPLN.

As can be seen from FIG. 2 and has already been explained above, light that enters coupling component 22 is totally reflected at the high reflective side and partially reflected at the other side. The partially reflected beam of one of the emitters is overlaid with the partially transmitted beam of the adjacent emitter and the combined beams follow the same path in the resonator. When using more than two semiconductor gain elements in an arrangement side by side, the coupling component 22 may be extended appropriately to allow multiple reflections between the two opposing surfaces. Furthermore, also several of such coupling components may be serially arranged.

The resulting beam coupled out of this laser cavity has nearly twice the power of a single VECSEL. This leads to a nearly fourfold power increase in the second harmonic radiation. Furthermore, the output coupling mirror may be formed of cheap broadband dielectric mirrors since no need for additional spectral narrowing of the coherently coupled laser beams is needed.

A further example of the proposed laser device is depicted in FIG. 3. In this integrated setup all required optical functionality is integrated into one properly shaped and coated optical device. The coupling component 22 forms a channel between the two opposing surfaces, one of which being highly reflective and the other partially transmissive for the fundamental laser radiation as indicated in FIG. 3. The surface, which the left beam hits first, is coated with a high reflection coating, while the first surface, which is hit perpendicular by the right beam, has an anti-reflection coating. The second surface, which both beams hit under 45°, has a coating with 50% reflection and combines both beams. The outcoupling mirror 23, which may be formed of an appropriate glass or plastic material, has a suited high reflection coating with an outcoupling degree designed for optimum operation of the device. The array of semiconductor gain elements 20, 21 may be the same as in FIG. 2.

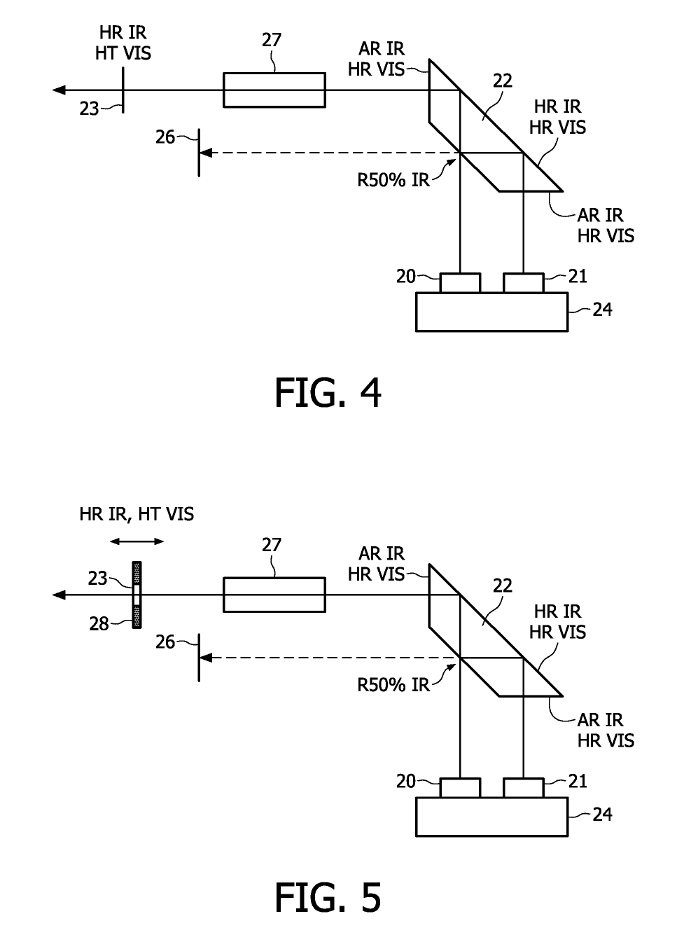

As already described, the proposed laser device is of course not limited to extracavity frequency conversion, but can also be used with the frequency converting medium inside of the laser cavity. Such a setup for intracavity frequency conversion is sketched in FIG. 4. In this device, the frequency converting crystal 27, for example a PPLN, is arranged between the coupling component 22 and the second end mirror 23. The second end mirror 23 is designed in this example to be highly reflective for the fundamental infrared radiation and to be highly transmissive for the generated second harmonic radiation in the visible wavelength range. Furthermore, the surfaces of the coupling component 22 are coated to be highly reflective for this visible radiation as indicated in the Figure. The array of semiconductor gain elements 20, 21 may be the same as in the previous FIGS. 2 and 3.

Let us now consider in detail two VECSEL lasers, which shall be coherently coupled in a set-up as described above. As already mentioned the extended cavities have different lengths for both devices. Let L₁ be the optical length of the laser cavity for the VECSEL with the shorter extended cavity. The extended cavity of the second laser may then have the length L₂=L₁+D. The additional length D is mainly given by the geometrical distance between both semiconductor gain elements on the array, but may also take into account optical path differences between the two beams in the coupling device. For optimum coupling of the two lasers the frequency overlap of their longitudinal cavity modes should be safeguarded. The frequency spacing of longitudinal modes in a laser cavity, sometimes also referred to as the Free Spectral Range (FSR), is given by

$$Δ {v}_{FSR} = \frac{c}{2 L}$$

(c: light velocity, L: cavity length).

The (half) width of the longitudinal modes Δv_{FWHM} depends on the finesse F of the resonator via the relation

$$Δ {v}_{FWHM} = \frac{Δ {v}_{FSR}}{F} ,$$

and the finesse is determined by the reflectivities R₁ and R₂ of the two mirrors, which define the respective extended cavity:

$$F = \frac{π \sqrt[4]{{R}_{1} {R}_{2}}}{1 - \sqrt{{R}_{1} {R}_{2}}} .$$

In general it cannot be expected, that two longitudinal modes from the two coupled cavities overlap perfectly within the spectral width of the laser gain profile, as the two cavities have different lengths, and the linewidths Δv_{FWHM} of the longitudinal modes are usually very small.

Consider as an example a typical design with R₁=99.8 and R₂=99.5% for both cavities and cavity lengths of L₁=8 mm and L₂=13 mm, respectively. The finesse of both cavities is then F≈896, and the free spectral ranges are Δv_{FSR1}≈18.7 GHz for the shorter and Δv_{FSR2}≈11.5 GHz for the longer cavity. The linewidths are with Δv_{FWHM1}≈20.9 MHz and Δv_{FWHM2}≈12.9 MHz considerably smaller, and additional measures are preferably taken to make sure that at least two longitudinal modes of the two coupled cavities mutually match.

The quite high finesse in the example above applies to devices, in which the infrared radiation generated in the semiconductor lasers is not directly used but converted to other, preferably visible, wavelengths within the extended cavity by means of e.g. SHG or upconversion. Here the reflectivity of the outcoupling mirror is chosen as high as possible in order to achieve a highest possible infrared intensity within the extended cavity and a lowest possible laser threshold. In applications, in which the generated infrared laser light shall be used directly, the outcoupling degree for infrared radiation will be higher, and a lower value for the reflectivity R₂ of the outcoupling mirror will be selected resulting in a lower finesse. But even with a reflectivity of say R₂=80% and a resulting finesse of F≈28 additional measures to optimize the frequency overlap of the longitudinal modes would be advantageous.

FIG. 5 shows a further example in which the above measures are taken. This example is nearly the same as that of FIG. 4. Therefore, the same components as that of FIG. 4 are labeled with the same reference signs and are not described again. The difference to the device of FIG. 4 is a translation stage 28, to which the second end mirror 23 is mounted. This translation stage 28, which may be a piezo-actuator, allows varying the length of both extended cavities. The required cavity length is controlled by measuring the output power of either the outcoupled infrared or of the generated visible radiation, for example with the help of a photodiode. This detector provides a suited feedback signal to a control unit which controls the longitudinal position of the outcoupling mirror 23 via the translation stage 28.

The following considerations shall yield the minimum longitudinal tuning range of the translation stage 28, which is necessary to make sure that an optimum overlap of the two involved longitudinal modes can be achieved. Consider the case, when two longitudinal modes of the two coupled laser devices ideally match. The wavelengths of the longitudinal cavity modes are given by the boundary condition that the resonator length is an integer multiple of the half wavelength, i.e. for both cavities:

L₁=m₁·λ/2 and L₂=L₁+D=m₂·λ/2

The integer numbers m₁ and m₂ represent the so called order of the longitudinal modes, and the orders of the matching modes fulfil the relation

L₁/m₁=(L₁+D)/m₂ (1)

which also shows that the shorter cavity has a lower mode order than the longer one (m₁<m₂).

Now consider a movement of the outcoupling mirror resulting in a length variation ΔL of the two coupled cavities. The resulting wavelength shift for each longitudinal mode is

Δλ=2/m·ΔL. (2)

As the wavelength shift is inverse proportional to the mode order the longitudinal modes of the shorter cavity will shift faster in wavelength than the longitudinal modes of the longer cavity. The next matching of adjacent longitudinal modes after increasing the cavity lengths by ΔL will thus be achieved when mode number m₁ from the first cavity coincides with mode number (m₂−1) of the second cavity, yielding the condition

(L₁+ΔL)/m₁=(L₁+D+ΔL)/(m₂−1). (3)

Inserting Eq. (1) into Eq. (3) yields after some calculations the maximum necessary longitudinal tuning range for the translation stage:

ΔL=L₁/(m₂−m₁−1)≈L₁/Δm with Δm=m₂−m₁.

Using the typical numbers of the above given example (L₁=8 mm, L₂=13 mm, D=5 mm) and assuming a typical infrared wavelength of λ=1 μm one gets m₁=16000, m₂=26000, Δm=10000 and finally ΔL≈800 nm. The resonance wavelength, at which the longitudinal modes of the two coherent cavities overlap, shifts according to Eq. (2) only by Δλ≈0.1 nm, which is usually way below the gain width of the semiconductor laser material.

While the invention has been illustrated and described in detail in the drawings and forgoing description, such illustration and description are to be considered illustrative or exemplary and not restrictive, the invention is not limited to the disclosed embodiments. The different embodiments described above and in the claims can also be combined. Other variations to the disclosed embodiments can be understood and effected by those skilled in the art in practicing the claimed invention, from a study of the drawings, the disclosure and the appended claims. For example, the proposed setup is not limited to linear arrays of semiconductor gain elements or to only two semiconductor gain elements but may also be used with two-dimensional arrays or arrays having a higher number of semiconductor gain elements. Furthermore, not only VCSEL based structures but also other structures like edge emitting laser structures can be used to achieve similar advantages. The exact construction of the layer structure is not critical in order to achieve the disclosed advantages, therefore different layer structures forming the first end mirror and the active gain medium may be used as known in the art.

In the claims, the word “comprising” does not exclude other elements or steps, and the indefinite article “a” or “an” does not exclude a plurality. The mere fact that measures are recited in mutually different dependent claims does not indicate that a combination of these measures can not be used to advantage. The reference signs in the claims should not be construed as limiting the scope of these claims.

### LIST OF REFERENCE SIGNS

1 layer structure
2 first end mirror (DBR)
3 active layer
4 partially transmissive DBR
5 electrical contacts
6 second end mirror
7 SHG crystal
8 outcoupled laser beam
9 heat sink
10 thermal lens
11 polarization control
20 first semiconductor gain element
21 second semiconductor gain element
22 coupling component
23 second end mirror (outcoupling mirror)
24 heat sink
25 combined single laser beam
26 beam stop
27 SHG crystal
28 translation stage

1. An extended cavity semiconductor laser device comprising:
an array of at least two semiconductor gain elements,
each of said semiconductor gain elements comprising a layer structure forming a first end mirror and an active medium,
a coupling component combining fundamental laser radiation emitted by said array of semiconductor gain elements to a single combined laser beam, and
a second end mirror reflecting at least part of said single combined laser beam back to said coupling component to form extended cavities with said first end mirrors.

2. The laser device according to claim 1, wherein said semiconductor gain elements are VECSEL components.

3. The laser device according to claim 1, wherein a frequency converting medium generating upconverted or second harmonic laser radiation is arranged between said coupling component and said second end mirror, said second end mirror being designed to form an outcoupling mirror for said upconverted laser radiation.

4. The laser device according to claim 1, wherein said second end mirror is designed to form an outcoupling mirror for said fundamental laser radiation.

5. The laser device according to claim 4, wherein a frequency converting medium generating upconverted or second harmonic laser radiation is arranged in a beam path of the outcoupled fundamental laser radiation.

6. The laser device according to claim 1, wherein said coupling component comprises one or several beam splitting regions.

7. The laser device according to claim 1, wherein said coupling component comprises two opposing reflective surfaces, a first of which being highly reflective for the fundamental laser radiation and a second of which having a reflectivity of between 40 and 60% and a transmittance of between 40 and 60% for the fundamental laser radiation.

8. The laser device according to claim 4, wherein said coupling component is attached to said second end mirror or said second end mirror is formed as a coating on said coupling component.

9. The laser device according to claim 1, wherein said second end mirror is attached to a translation stage, said translation stage being designed to allow varying cavity lengths of the device by displacing said second end mirror.

10. The laser device according to claim 9, wherein an optical detector is arranged to measure an intensity of laser radiation coupled out of the device, said optical detector being connected to a control unit controlling said translation stage dependent on the measured intensity to stabilize and/or to maximize the intensity of the laser radiation coupled out of the device.

11. RGB laser source comprising at least one laser device according to claim 1 with a frequency converting medium inside or outside of the cavities.

12. A projection device comprising at least one laser device according to claim 1 with a frequency converting medium inside or outside of the cavities as a light source.
